(19) United States
(12) Patent Application Publication
(10) Pub. No.: US 2025/0183687 A1
(43) Pub. Date: Jun. 5, 2025

(54) CHARGING APPARATUS FOR WEARABLE DEVICE

(71) Applicant: ULTRAHUMAN HEALTHCARE PVT LTD, Bangalore South (IN)

(72) Inventors: Apoorv Shankar, Bangalore (IN); Mainak Mitra, Kolkata (IN); Mohit Kumar, Bangalore (IN); Adhit Shet, Bengaluru (IN); Bhuvan Srinivasan, Bangalore (IN); Vatsal Singhal, Bengaluru (IN)

(73) Assignee: ULTRAHUMAN HEALTHCARE PVT LTD, Bangalore South (IN)

(21) Appl. No.: 19/045,892

(22) Filed: Feb. 5, 2025

Related U.S. Application Data
(63) Continuation of application No. PCT/IN2024/051530, filed on Aug. 21, 2024.

(30) Foreign Application Priority Data
Aug. 22, 2023 (IN) 202341056232

(51) Int. Cl. H02J 7/00; H02J 50/10; H02J 50/90; H05K 7/14

(52) U.S. Cl. CPC H02J 7/0044; H02J 7/0047; H02J 50/90; H05K 7/1432; H02J 50/10

(57) ABSTRACT

The proposed invention relates to a charging apparatus for a wearable device. The charging apparatus comprises a base unit and a top unit. The base unit comprises a Printed Circuit Board (PCB). The PCB may include an input connector for receiving an Alternating Current (AC) power. Further, the PCB includes a rectifier for converting the AC power to a Direct Current (DC) power. The top unit is detachably positioned over the base unit and electrically connected with the rectifier for receiving the DC power. The top unit includes a wireless charging coil for wireless charging of the wearable device.

This application is a bypass continuation and claims priority of International Application No. PCT/IN2024/051530; filed Aug. 21, 2024, which claims priority to Indian Application No. 202341056232, filed Aug. 22, 2023, each of which is hereby incorporated herein by reference in its entirety.

### FIELD OF INVENTION

### Background

Regular health and fitness monitoring devices, especially wearable devices, are commonly used now-a-days. For an example, electronic rings are extremely popular. However, a household may have multiple electronic rings, each requiring different chargers as they may be of varying sizes.

With advancement in technology, new features may be introduced in such electronic rings and a user may upgrade to a new electronic ring. In such a case, the user is bound to change charging apparatus also as a particular charging apparatus may be configured to charge an electronic ring of a particular size. This increases cost burden on the user and also increases electronic waste.

Thus, there is a need for a charger that may be used for charging electronic ring of varying sizes.

### Objects of the Invention

A general objective of the present invention is to offer a modular charging apparatus.

Another objective of the invention is to provide a charging apparatus for wearable devices.

Yet another objective of the invention is to provide a charging apparatus for electronic ring of different sizes.

### SUMMARY OF THE INVENTION

The present invention relates to a charging apparatus comprising a top unit and a base unit. The base unit may be a core unit comprising a power converter. The power converter may supply power to the top unit. The top unit may be a replaceable unit configured to hold electronic ring of a particular size.

In one aspect, the top unit may comprise a wireless charging coil for charging wireless charging coil of the electronic ring.

In one aspect, the top unit and the base unit may be connected by male and female connectors for transfer of power.

In one aspect, the top unit and the base unit may be magnetically snapped together.

Other aspects and advantages of the invention will become apparent from the following description, taken in conjunction with the accompanying drawings, illustrating by way of example the principles of the invention.

### BRIEF DESCRIPTION OF THE DRAWINGS

The accompanying drawings constitute a part of the description and are used to provide further understanding of the present invention. Such accompanying drawings illustrate the embodiments of the present invention which are used to describe the principles of the present invention. The embodiments are illustrated by way of example and not by way of limitation in the figures of the accompanying drawings in which like references indicate similar elements. It should be noted that references to “an” or “one” embodiment in this invention are not necessarily to the same embodiment, and they mean at least one. In the drawings:

FIG. 1 illustrates an exploded view of the charging apparatus, in accordance with an embodiment of the present invention;

FIG. 2 illustrates a sectional view of the base unit of the charging apparatus, in accordance with an embodiment of the present invention;

FIGS. 3(a) and 3(b) illustrate a perspective view of the base unit and the top unit of charging apparatus, in accordance with an embodiment of the present invention;

FIG. 4 illustrates a top view of the base unit of the charging apparatus, in accordance with an embodiment of the present invention;

FIG. 5 illustrates a perspective view of an assembled charging apparatus with the electronic ring, in accordance with an embodiment of the present invention;

FIG. 6 illustrates a sectional view of the top unit of the charging apparatus, in accordance with an embodiment of the present invention.

### DETAILED DESCRIPTION OF THE INVENTION

The detailed description set forth below in connection with the appended drawings is intended as a description of various embodiments of the present invention and is not intended to represent the only embodiments in which the present invention may be practiced. Each embodiment described in this disclosure is provided merely as an example or illustration of the present invention, and should not necessarily be construed as preferred or advantageous over other embodiments. The detailed description includes specific details for the purpose of providing a thorough understanding of the present invention. However, it will be apparent to those skilled in the art that the present invention may be practiced without these specific details.

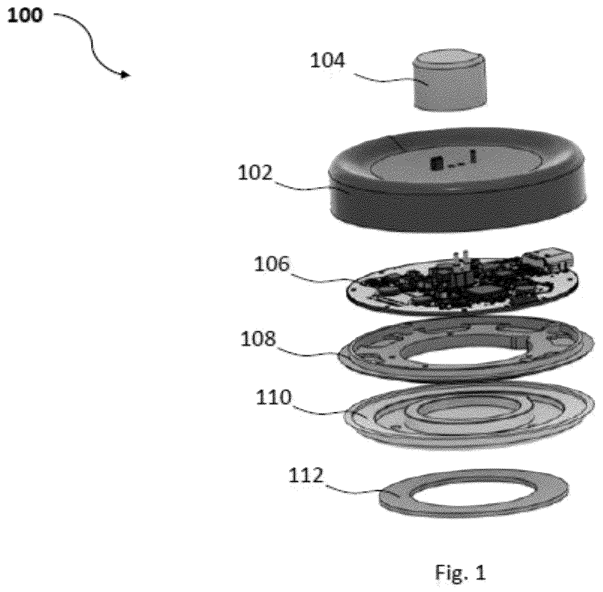

The proposed invention relates a charging apparatus. The charging apparatus may be a modular charging apparatus for charging wearable devices, especially an electronic ring. Modularity may refer to a design strategy of creating an apparatus that consists of separate components or units that can be easily connected or detached. The charging apparatus may comprise a base unit and a top unit. FIG. 1 illustrates an exploded view of the charging apparatus, in accordance with an embodiment of the present invention. The charging apparatus 100 may comprise a base unit 102 and a top unit 104. The base unit 102 may form a core unit of the charging apparatus 100. The top unit 104 may be detached from the base unit 102. The top unit 104 may be configured to hold a wearable device, such as electronic ring of a particular size. When a user swaps to the electronic ring of a different size, only the top unit 102 may be replaced for charging the electronic ring of the different size.

The base unit 102 may comprise a Printed Circuit Board (PCB) 106. The PCB 106 may comprise a rectifier for converting Alternating Current (AC) wall voltage to a Direct Current (DC) for supply of the DC current to the top unit 104. The PCB 106 may also comprise at least one electric contact means for conducting DC to the top unit 104. The PCB 106 may further comprise input connector to receive an AC wall voltage from a power source. The input connector is connected to the AC power source by a power cord, such as three-pin power cord and two-pin power chord. The PCB 106 may be positioned above a light guide 108. The light guide 108 may direct light from a Light Emitting Diode (LED) to an indicator (not illustrated in FIG. 1) on a top surface of the base unit 102 to indicate an ON/OFF power status of the charging apparatus. The PCB 106 and the light guide 108 may be covered by a base plate 110 from bottom. The base plate 110 may be positioned on a pad 112. The pad 112 may be metallic. The metal adds extra weight to the base unit 102.

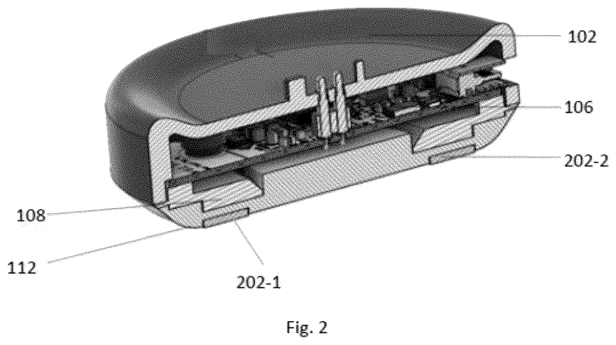

FIG. 2 illustrates a sectional view of the base unit 102 of the charging apparatus 100, in accordance with an embodiment of the present invention. As illustrated in FIG. 2, the light guide 108 may be connected with the PCB 106 from bottom side. The PCB 106 and the light guide 108 may be enclosed within the base unit 102. The base unit 102 may be positioned on the pad 112. The pad 112 may have friction contacts 202-1, 202-2 disposed at a bottom surface so that the base unit 102 does not move freely.

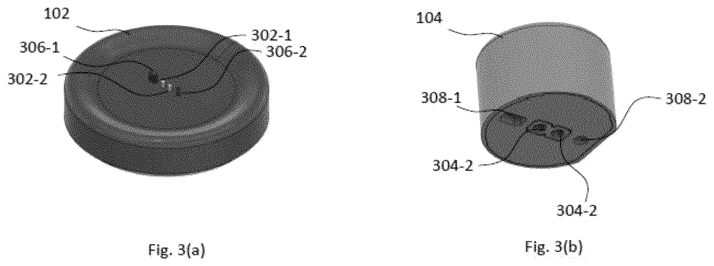

FIGS. 3(a) and 3(b) illustrate a perspective view of the base unit and the top unit of charging apparatus, in accordance with an embodiment of the present invention. The base unit 102 may comprise male connectors present on the top surface. The top unit 104 may comprise female connectors present on a bottom surface. In one implementation, the male connectors may be male pogo pins 302-1, 302-2 having corresponding female pogo pins 304-1, 304-2. The male pogo pins 302-1, 302-2 and the female pogo pins 304-1, 304-2 may serve a dual purpose, acting as connectors for power transfer from the base unit 102 to the top unit 104. The male pogo pins 302-1, 302-2 and the female pogo pins 304-1, 304-2 may also ensure structural integrity of the ensemble of the base unit 102 and the top unit 104. The integration of male pogo pins 302-1, 302-2 with the female pogo pins 304-1, 304-2, contributes to transfer of power from the base unit 102 to the top unit 104 while simultaneously bolstering structural cohesion. The male pogo pins 302-1, 302-2 and the female pogo pins 304-1, 304-2 may be engineered to align precisely upon connection, optimizing the efficiency of power transmission and reducing potential energy loss.

Further, the base unit 102 may also comprise pins 306-1, 306-2 present around the pogo pins 302-1, 302-2. The pins 306-1, 306-2 may be inserted in corresponding slots 308-1, 308-2 present on the bottom surface of the top unit 104. By insertion of the pins 306-1, 306-2 in the slots 308-1, 308-2, the base unit 102 may be locked with the top unit 104 in a correct orientation to assemble the charging apparatus 100.

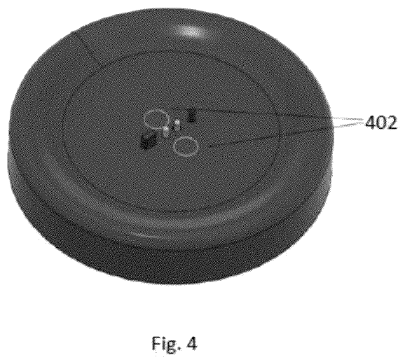

FIG. 4 illustrates a top view of the base unit of the charging apparatus, in accordance with an embodiment of the present invention. The base unit 102 and the top unit 104 may comprise magnets 402-1, 402-2 (collectively referred to as 402) present around the male pogo pins 302-1, 302-2 and the female pogo pins 304-1, 304-2. The magnets 402 may enable the base unit 102 and the top unit 104 to magnetically snap together and maintain contact between the pogo pins 302-1, 302-2. The magnets 402 may ensures secure attachment between the base unit 102 and the top unit 104, thereby heightening stability of the charging apparatus 100. Importantly, this magnetic interaction also plays a pivotal role in sustaining contact between the male pogo pins 302-1, 302-2 with the female pogo pins 304-1, 304-2.

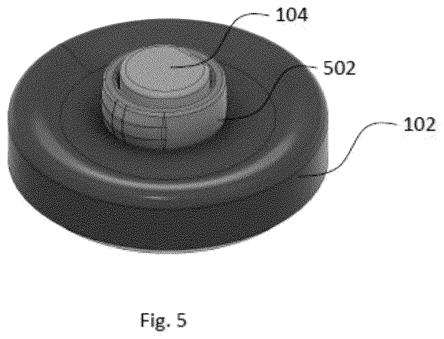

FIG. 5 illustrates a perspective view of an assembled charging apparatus with the electronic ring, in accordance with an embodiment of the present invention. An electronic ring 502 may be positioned around the top unit 104 in contact with a side surface of the top unit 104 for wireless charging the electronic ring 502. For charging the electronic ring of a different size, the top unit 104 may be replaced, allowing users to attach new modules to their existing base unit 102, rather than needing to replace the entire charging apparatus.

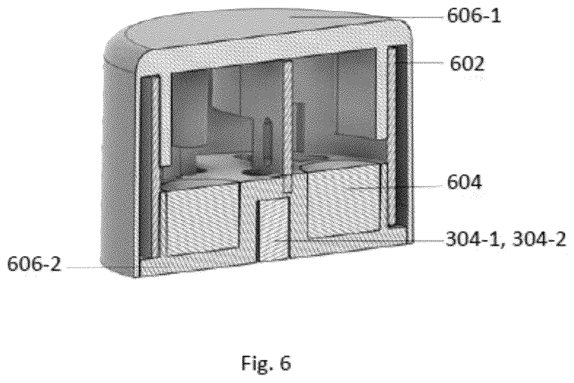

FIG. 6 illustrates a sectional view of the top unit of the charging apparatus, in accordance with an embodiment of the present invention. The top unit 104 may comprise a circuitry for wireless charging of the electronic ring. For wireless charging, the top unit 104 may comprise a wireless charging coil 602 present on a side surface of the top unit 104. Electromagnetic field generated by a coil present in the wireless charger may get coupled with a wireless charging coil of the electronic ring when the electronic ring is present in contact with the top unit 104. Through coupling of the electromagnetic field, power from the top unit 104 may be received and stored in the battery of the electronic ring. FIG. 6 further depicts female pogo pins 304-1, 304-2 present on bottom surface of the top unit 104. The top unit 104 further comprises magnets 604 present adjacent to the wireless charging coil 602 for snapping the top unit 104 with the base unit 102. The circuitry for wireless charging and other components may be enclosed within a top enclosure 606-1 and a bottom enclosure 606-2.

The present invention offers versatility and adaptability to a user by allowing customization of the charging apparatus for different sizes of electronic rings. When an electronic ring with new technologies or features become available and users switch to those electronic rings, users can simply purchase and attach new top unit to existing base unit of the charging apparatus. With the ability to retain the majority of components of the charging apparatus within the base unit, the invention promotes sustainability and cost-efficiency. The present invention further reduces electronic waste since users only need to replace the smaller, more specific replaceable top unit when necessary. It also reduces the cost associated with upgrading or adapting to new technologies, as users can opt to update only the necessary components.

In the above detailed description, reference is made to the accompanying drawings that form a part thereof, and illustrate the best mode presently contemplated for carrying out the invention. However, such description should not be considered as any limitation of scope of the present unit. The structure thus conceived in the present description is susceptible of numerous modifications and variations, all the details may furthermore be replaced with elements having technical equivalence.

We claim:

1. A charging apparatus for a wearable device, comprising:
a base unit comprising a printed circuit board (PCB), wherein the PCB includes:
an input connector for receiving an Alternating Current (AC) power;
a rectifier for converting the AC power to a Direct Current (DC) power; and
a top unit detachably positioned over the base unit and electrically connected with the rectifier for receiving the DC power, wherein the top unit includes a wireless charging coil for wireless charging of the wearable device encircling the top unit.

2. The charging apparatus as claimed in claim 1, wherein the input connector is connected to an AC power source by a three-pin power chord or a two-pin power chord.

3. The charging apparatus as claimed in claim 1, wherein the base unit and the top unit are detachably connected via a locking mechanism.

4. The charging apparatus as claimed in claim 3, wherein the locking mechanism is selected from a group consisting of magnetic locks, threaded fitting, and push lock.

5. The charging apparatus as claimed in claim 1, further comprises a light guide beneath the PCB to display a status of charging of the wearable device.

6. The charging apparatus as claimed in claim 1, further comprises a base plate fixed at bottom of the base unit to cover components of the base unit.

7. The charging apparatus as claimed in claim 1, further comprises a pad fixed beneath the base unit for restricting the slipping and free movement of the base unit.

8. The charging apparatus as claimed in claim 7, wherein the pad fixed beneath the base unit is made of metal to add extra weight and enhance stability of the base unit.

9. The charging apparatus as claimed in claim 1, further comprises male connectors configured to engage with corresponding female connectors for electrical connection and structural stability.

10. The charging apparatus as claimed in claim 1, wherein the base unit further comprises pins configured to engage with corresponding slots in the top unit to ensure correct orientation and secure positioning.

11. A charging apparatus for a wearable device, comprising:
a base unit comprising a printed circuit board (PCB), wherein the PCB includes:
an input connector for receiving an Alternating Current (AC) power;
a rectifier for converting the AC power to a Direct Current (DC) power; and
a top unit detachably positioned over the base unit and electrically connected with the rectifier for receiving the DC power, wherein the top unit is of variable size, enabling compatibility with different sizes of the wearable device, wherein the top unit includes a wireless charging coil for wireless charging of the wearable device encircling the top unit.

12. The charging apparatus as claimed in claim 11, wherein the input connector is connected to an AC power source by a three-pin power chord or a two-pin power chord.

13. The charging apparatus as claimed in claim 11, wherein the base unit and the top unit are detachably connected via a locking mechanism.

14. The charging apparatus as claimed in claim 13, wherein the locking mechanism is selected from a group consisting of magnetic locks, threaded fitting and push locks.

15. The charging apparatus as claimed in claim 11, further comprises a light guide beneath the PCB to display a status of charging of the wearable device.

16. The charging apparatus as claimed in claim 11, further comprises a base plate fixed at bottom of the base unit to cover components of the base unit.

17. The charging apparatus as claimed in claim 11, further comprises a pad fixed beneath the base unit for restricting the slipping and free movement of the base unit.

18. The charging apparatus as claimed in claim 17, wherein the pad fixed beneath the base unit is made of metal to add extra weight and enhance stability of the base unit.

19. The charging apparatus as claimed in claim 11, further comprises male connectors configured to engage with corresponding female connectors for electrical connection and structural stability.

20. The charging apparatus as claimed in claim 1, wherein the base unit further comprises pins configured to engage with corresponding slots in the top unit to ensure correct orientation and secure positioning.
